(19) United States
(12) Patent Application Publication
(10) Pub. No.: US 2008/0090394 A1
(43) Pub. Date: Apr. 17, 2008

(54) Temperature Synthesis of Hexagonal Zns Nanocrystals as Well as Derivatives with Different Transition Metal Dopants Using the Said Method

(75) Inventors: John Q. Xiao, Neward, DE (US); Yuwen Zhao, Newark, DE (US)

Correspondence Address: RATNERPRESTIA, P.O. BOX 1596, WILMINGTON, DE, 19899, US

(73) Assignee: UNIVERSITY OF DELAWARE, Newark, DE (US)

(21) Appl. No.: 11/574,372

(22) PCT Filed: Aug. 24, 2005
(86) PCT No.: PCT/US05/30041

§ 371 Date: Oct. 9, 2007

Related U.S. Application Data
(60) Provisional application No. 60/605,944, filed on Aug. 31, 2004.

(51) Int. Cl. H01L 21/22; C01G 9/08; B01J 8/00

(52) U.S. Cl. 438/542; 423/566.1; 423/561.1; 423/659; 257/E21.135

(57) ABSTRACT

A method to fabricate semiconductor nanocrystals which comprises dissolving a metal source in a first solvent that contains at least one functional —OH group to form a mixture and heating the mixture to form a solution 1 and dissolving a X source in a second solvent which contains at least one functional —OH group, to form a solution 2 and mixing solution 2 and then combining solution 2 into solution 1, and heating and separating the solution out, to produce semiconductor nanocrystals.

### RELATED APPLICATIONS

This application claims benefit to U.S. provisional application 60/605,944 filed Aug. 31, 2004, which is incorporated by reference in its entirety for all useful purposes.

### FIELD OF THE INVENTION

The current invention is directed to a new low-temperature wet-chemistry synthetic technique to fabricate high-temperature polymorph of zinc-blend ZnS (“zinc sulfide”), hexagonal (wurtzite) ZnS as well as derivatives with different transition metal dopants, in the form of nanocrystals.

### BACKGROUND OF THE INVENTION

As an important member in the family of wide-gap semiconductors ZnS has been extensively investigated (Monroy E.; Omnes F.; Calle F. Semicond. Sci. Technol. 2003, 18, R33). ZnS is among the oldest and probably the most important materials used as phosphor host (Chen R.; Lockwood D. J. J. Electrochem. Soc. 2002, 149, s69). By doping ZnS with different metals, ((a) Bhargava R. N.; Gallagher D.; Hong X.; Nurmikko D. Phys. Rev. Lett. 1994, 72, 416; (b) Marking G. A.; Warren C. S.; Payne B. J. U.S. Pat. No. 6,610,217 B2, 2003; (c) Lee S.; Song D.; Kim D.; Lee J.; Kim S.; Park I. Y.; Choi Y. D. Mater. Lett. 2004, 58, 342; (d) Alshawa A. K.; Lozykowski H. J. J. Electrochem. Soc. 1994, 141, 1070) a variety of luminescent properties excited by UV, X-rays, cathode rays as well as electroluminescence have been observed. Owing to its excellent transmission property and its high index of refraction (2.27 at 1 μm), ZnS is also a very attractive candidate for applications in novel photonic crystal devices operating in the region from visible to near IR (Park W.; King J. S.; Neff C. W.; Liddell C.; Summers C. J. Phys. Stat. Sol., (b) 2002, 229, 946). In the last decade, numerous results ((a) Murry C. B.; Norris D. J.; Bawendi M. G. J. Am. Chem. Soc. 1993, 115, 8706; (b) Nanda J.; Sapra S.; Sarma D. D.; Chandrasekharan N.; Hodes G. Chem. Mater. 2000, 12, 1018; (c) Yu W. W.; Peng X. Angew. Chem. Int. Ed. 2002, 41, 2368; (d) Pradhan N.; Katz B.; Efrima S. J. Phys. Chem. 2003, 107, 13843; (e) Yu S. H.; Yoshimura M. Adv. Mater. 2002, 14, 296; (f) Joo J.; Na H. B.; Yu T.; Yu J. H.; Kim Y. W.; Mu F.; Zhang J. Z.; Hyeon T. J. Am. Chem. Soc. 2003, 125, 11100; (g) Ma C.; Li D. M.; Wang Z. L. Adv. Mater. 2003, 15, 228; (h) Jiang Y.; Meng X. M.; Liu J.; Hong Z. R.; Lee C. S.; Lee S. T. Adv. Mater. 2003, 15, 1195; (i) Zhu Y. C.; Bando Y.; Xue D. F.; Golberg D. J. Am. Chem. Soc. 2003, 125, 16196; (j) Zhu Y. C.; Bando Y.; Xue D. F. Appl. Phys. Lett. 2003, 82, 1769) have been reported on the synthesis of nanometer scale semiconductor crystals (quantum dots, nanowires, nanorods etc.) because their properties, due to quantum confinement effect, ((a) Brus L. J. Phys. Chem. 1986, 90, 2555; (b) Wang Y.; Herron N. J. Phys. Chem. 1991, 95, 525; (c) Alivisatos, A. P. J. Phys. Chem. 1996, 100, 13226) dramatically change and, in most cases, improve as compared with their bulk counterparts ((a) Alivisatos, A. P. Science 1996, 271, 933; (b) Chen C. C.; Herhold A. B.; Johnson C. S.; Alivisatos, A. P. Science 1997, 276, 398). Among them, ZnS nanocrystals (NCs), again, have been receiving much of interests. The structure evolution of ZnS NCs with particle size and their chemical environment has also been the center of research ((a) Qadri S. B.; Skelton E. F.; Hsu D.; Dinsmore A. D.; Yang J.; Gray H. F.; Ratna B. R. Phys. Rev. B 1999, 60, 9191; (b) Huang F.; Zhang H.; Banfield J. F. J. Phys. Chem. B, 2003, 107, 10475; (c) Zhang H.; Huang F.; Gilbert B.; Banfield J. F. J. Phys. Chem. B 2003, 107, 13051; (d) Zhang H.; Gilbert B.; Huang F.; Banfield J. F. Nature, 2003, 424, 1025).

We have found that ZnS NCs mostly synthesized by colloid chemistry usually have the cubic zinc blende (sphalerite) structure (Joo J.; Na H. B.; Yu T.; Yu J. H.; Kim Y. W.; Mu F.; Zhang J. Z.; Hyeon T. J. Am. Chem. Soc. 2003, 125, 11100) which is a stable phase at low temperatures for ZnS. Hexagonal (wurtzite) phase is the high-temperature polymorph of sphalerite which can be formed at temperatures higher than 1000° C. (Yu S. H.; Yoshimura M. Adv. Mater. 2002, 14, 296), (Qadri S. B.; Skelton E. F.; Hsu D.; Dinsmore A. D.; Yang J.; Gray H. F.; Ratna B. R. Phys. Rev. B 1999, 60, 9191). There were only a few cases (Yu S. H.; Yoshimura M. Adv. Mater. 2002, 14, 296), (Ma C.; Li D. M.; Wang Z. L. Adv. Mater. 2003, 15, 228) and ((a) Wang Y.; Zhang L.; Liang C.; Wang G.; Peng X. Chem. Phys. Lett. 2002, 357, 314; (b) Qiao Z. P.; Xie G.; Tao J.; Nie Z. Y.; Lin Y. Z.; Chen X. M. J. Solid State Chem. 2002, 166, 49; (c) Takata, S.; Minami, T.; Miyata, T.; Nanto, H. J. Crystal Growth 1988, 86, 257) where pure wurtzite ZnS NCs were obtained either with high temperature or with solvothermal reaction. One example (Yu S. H.; Yoshimura M. Adv. Mater. 2002, 14, 296) is to thermally decompose the precursor ZnS.(NH₂CH₂CH₂NH₂)_{0.5} formed by solvothermal reaction of Zn²⁺ with thiourea in ethylene-diamine medium at 120-180° C. Even in that case, a minimum temperature of 250° C. is required to obtain wurtzite ZnS nanosheets, not to mention the solvothermal condition required to generate the precursor.

U.S. Pat. No. 5,498,369 disclosed a method of manufacturing ZnS fine particles of about 200 nm by wet-chemical precipitation from aqueous zinc salt solutions in which ZnS is precipitated onto nuclei introduced into the solution.

The current invention differs from the present technology in the aspects of reaction medium, reaction temperature and the morphology. The current invention is an entirely new chemistry which may be extended to variety of materials such as cadmium sulfide (“CdS”), lead sulfide (“PbS”), mercury sulfide (“HgS”) etc. as well as their derivatives with various transition metal dopants. The process can be carried out in very mild reaction condition and thus can be easily adopted in large scale manufacturing. In addition, all chemicals involved are environmentally benign.

The main novelty and surprising aspect of the current invention is to obtain the high-temperature polymorph of zinc-blend ZnS, i.e., wurtzite ZnS, nanocrystals at vary low temperatures (˜150° C.). It is obviously advantageous from the energetic point of view in terms of large scale production, and also important for better understanding the mechanism determining the crystalline structure of nanoscale semiconductors.

### SUMMARY OF THE INVENTION

An object of this invention was to find a novel and facile low-temperature (150° C.) synthesis of hexagonal ZnS NCs as shown in FIG. 1. The synthesis is very simple and yet different from conventional colloid chemistry methods. The method may also be applied to fabricate other semiconductor such as CdS NCs. The surprising ability of achieving high temperature stable phase at very low temperatures not only provides economically viable route for applications, but also opens a new avenue to study structural kinetics and chemistry of semiconductor NCs.

To fabricate other materials such as CdS, PbS, HgS, we just need to replace ZnCl₂ with other metal salts like chlorides (CdCl₂, PbCl₂, HgCl₂ etc.) and acetates (CdAc₂, PbAc₂ and HgAc₂ etc.), respectively.

The method described in the current invention may be readily used for doping the semiconductor NCs with transition metals like Ag, Cu, Co, Cr, V, Mn, etc. using the salts of these metals to substitute part of the salts for semiconductor NCs.

The materials produced by the current invention with appropriate transition metal doping can be used as phosphor (blue, green) for color picture display, other types of luminescent (photo-, x-ray-, cathode- and electro-luminescent) devices. In addition, the materials produced by the current invention with or without appropriate dopants have potential for applications in spin-dependent electronics based on diluted magnetic semiconductors, in novel photonic crystal devices operating in the region from visible to near IR. More importantly, the method described in the current invention may be readily used to dope the parent compound with variety of transition metals for the application in spintronics as mentioned above.

To avoid agglomeration problem, one can introduce suitable surfactants in the production process. The size of NCs can be increased by using the nanocrystals produced by current invention as seeds for further crystal growth to get larger particle size for particular application.

### BRIEF DESCRIPTION OF THE FIGURES

FIG. 1: Typical TEM graphs showing the as-prepared wurtzite ZnS nanocrystals with average size less than 5 nm. In the higher magnification graph (FIG. 1C), the lattice fringe pattern clearly reveals the particles are well crystallized.

FIG. 2 illustrates XRD patterns for ZnS nanocrystals obtained in glycerol (1: blue), diethylene glycol (2: green) and ethylene glycol (3: red) without tetramethylammonium hydroxide and in ethylene glycol with tetramethylammonium hydroxide (4: black). Curves are offset in y-axis for clarity. Vertical magenta bars indicate standard hexagonal ZnS peak positions from JCPDS No. 80-0007.

FIG. 3 illustrates UV/Vis spectra of ZnS nanocrystals dispersed in ethyl alcohol. Curves 1, 2 and 3 are for samples obtained at initial stages (150° C., 10 mins) using glycerol, diethylene glycol and ethylene glycol as reaction medium, respectively. Curve 4 is for samples obtained at 150-165° C. for 2 hours. Curve 4 has an absorption band centered at about 325 nm, corresponding to the onset of UV absorption and the particle size is about 4.5 nm. The samples obtained at initial stage all have strongly blue-shifted absorption peaks at 285 nm indicating much smaller particle size about 2.5 nm.

### DETAILED DESCRIPTION OF THE INVENTION

The invention relates to a method to fabricate semiconductor nanocrystals which comprises dissolving a metal source in a first solvent that contains at least one functional —OH group to form a mixture and heating the mixture to form a solution 1 and dissolving a X source in a second solvent which contains at least one functional —OH group, to form a solution 2 and mixing solution 2 and then combining solution 2 and solution 1, and heating the combined mixture of solutions 1 and 2 and separating the solution out, to produce semiconductor nanocrystals and wherein said X source contains an element from Group 15 or 16 of the periodic table of elements.

The metal source preferably contains at least one element from Groups 12, or 13 from the periodic table of elements or Pb or Sn. Group 12 includes Zn, Cd, Hg, and Group 13 includes B, Al, Ga, In or TI. The metal source preferably contains a reactable group such as a halide, such as Cl, Br, F, or I, and most preferably Cl; or an acetate (Ac₂). Examples of preferred metal sources include but are not limited to ZnCl₂, ZnAc₂, CdCl₂, CdAc₂, HgCl₂, HgAc₂, PbCl₂, PbAc₂,CdBr₂, Cd(NO₃)₂, CdSO₄, Zn(NO₃)₂, ZnSO₄, Zinc propionate etc.

The X source contains an element from Groups 15 and 16 of the periodic table of elements. Group 15 includes N, P, AS, Sb and Bi and the elements of Group 16 include O, S, Se, Te and Po.

Examples of the X source include any composition containing these elements such as but not limited to thiourea, carbamide, hydrogen sulfite, etc.

The first and second solvent that contains at least one functional OH group can be the same or different. The solvent can be water, glycols (contain two functional OH groups), polyols (containing more than one OH group). Glycols are more preferable. The solvents can be ethylene glycol, propylene glycol, methyl glycol, diethylene glycol, diglycol, neopentyl glycol and some other solvents containing hydroxy function group.

Polyols or poly-alcohols like ethylene glycol (“EG”) have been widely used for synthesizing nanoparticles of transition metals ((a) Fievet F.; Figlarz M.; Lagier J. P. U.S. Pat. No. 4,539,041, 1985; (b) Viau G.; Fievet-Vincent F.; Fievet F. Solid State Ionics 1996, 84, 259; (c) Fievet F. in Fine Particles—Synthesis, Characterization, and Mechanisms of Growth; Tadao Sugimoto, Eds.; Marcel Dekker: New York, 2000; pp 460-496; (d) Sun Y.; Xia Y. Science 2002, 298, 2176) and semiconductors ((a) Ding T.; Zhang J. R.; Hong J. M.; Zhu J. J. Chen H. Y. J. Cryst. Growth 2004, 260, 527; (b) Chen D.; Shen G.; Tang K.; Lei S.; Zheng H.; Qian Y. J. Cyst. Growth 2004, 260, 469) assisted by either ultrasonic (Ding T.; Zhang J. R.; Hong J. M.; Zhu J. Chen H. Y. J. Cryst. Growth 2004, 260, 527) or microwave energy (Chen D.; Shen G.; Tang, K.; Lei S.; Zheng H; Qian Y. J. Cryst. Growth 2004, 260, 469). We adopted EG as the reaction medium for synthesizing ZnS NCs.

The heating is preferably conducted at a temperature less than the boiling point of the solvent. Obviously, if the temperature is above the boiling point of the solvent, the solvent will evaporate. Preferably, the heating of the reaction not heated above the boiling point of the mixture. The heating is preferably conducted at approximately 150° C. to approximately 165° C.

An optional surfactant can be added. The surfactant can help prevent the nanocrystals from agglomerating. The surfactants can be but are not limited to tetramethylammonium hydroxide (TMAH), Cetyltrimethyl Ammonium Bromide (CTAB) etc.

### EXAMPLE

As an example, we describe a typical experiment for producing wurtzite ZnS nanocrystals as following: 7.34 mmol anhydrous ZnCl₂ and 14.86 mmol tetramethylammonium hydroxide (TMAH) are dissolved into 50 ml EG and heated to 100° C. (Solution 1). The TMAH serves as solely surfactant to prevent the formed nanocrystals from agglomeration and does not play a significant role in the formation of hexagonal ZnS.

7.34 mmol thiourea is separately dissolved into another 50 ml EG (Solution 2). Under vigorous magnetic stirring, solution 2 is then quickly injected into solution 1. The mixed solution is clear until the solution is heated up to 150° C., then after a short time (about 10 minutes) the solution becomes milky-white indicating the formation of ZnS NCs. At this initial stage, the first aliquot of reaction solution is taken out for characterization of materials at this stage. The remaining solution is then maintained at 150-165° C. for 2 hours to complete the crystal growth. The products are then separated from the reaction solution using centrifugation, and washed with ethyl alcohol twice and acetone twice, dried in a desiccator. The color of reaction solution became milky-white mixed with light yellow, a second aliquot of reaction solution is taken out. The rest of the solution is heated further to boiling (˜194° C.) and refluxing for another 1 hour and used as the third aliquot. All three aliquots are cooled down to room temperature (“RT”), and ZnS nanocrystals are separated from the reaction solution by centrifugation, washed with acetone and ethanol, and finally dried in a desiccator. The dried ZnS powders, which can be redispersed in ethanol for UV/Vis spectrum measurements, are used for structural characterization using x-ray diffraction (“XRD”) and transmission electron microscopy (“TEM”).

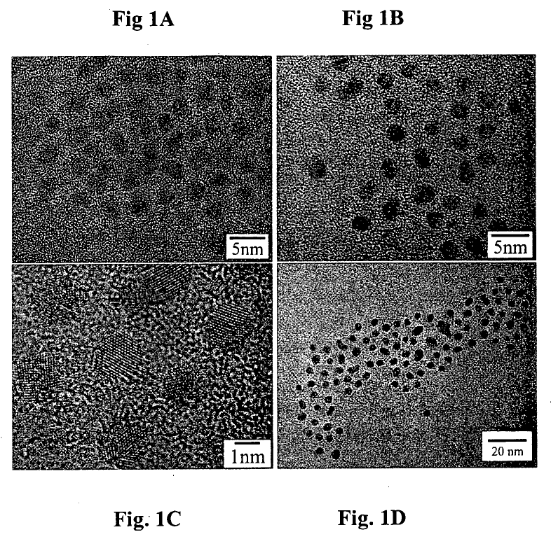

As demonstrated in FIG. 1a, the as-synthesized ZnS NCs from the second aliquot are quite uniform in both shape and size. The average size estimated from FIG. 1 is 4.2 nm with standard deviation of 0.6 nm. The higher magnification TEM graph in FIG. 1 (bottom left) clearly shows lattice fringe pattern illustrating that the nanoparticles are well crystallized.

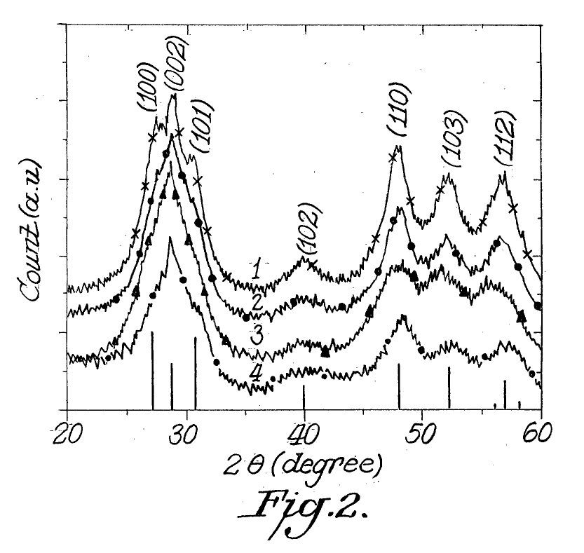

XRD patterns shown in FIG. 2 for ZnS nanoparticles obtained in different polyols like glycerol (1: blue), diethylene glycol (2: green) and ethylene glycol (3: red) without tetramethylammonium hydroxide and in ethylene glycol with tetramethylammonium hydroxide (4: black) match well to hexagonal ZnS (JCPDS No. 80-0007, vertical bars). The diffraction peaks are significantly broadened because of the very small crystallite size. We cannot exclude the existence of cubic ZnS phase from XRD patterns alone because of the large similarity in the structures between cubic and hexagonal ZnS. However, close inspection of randomly selected individual particles by HRTEM does not seem to reveal any cubic phase. One thing is clear that the hexagonal ZnS phase is indeed formed at temperature as low as 150° C. under ambient condition. From our experimental data, it is also evident that neither refluxing at 194° C. nor annealing at 250° C. in Ar significantly changes the diffraction pattern, implying the size of ZnS crystallites does not increase at higher reaction temperature and the nanoparticles are well separated. It should be mentioned that in the synthesis, it is essential after the injection of solution 2 into solution 1, the temperature of the reaction solution to be maintained below 174-177° C. for certain time, otherwise thiourea decomposes resulting in very low ZnS yield. This is probably also the reason why the crystallites do not grow larger after refluxing at 194° C.

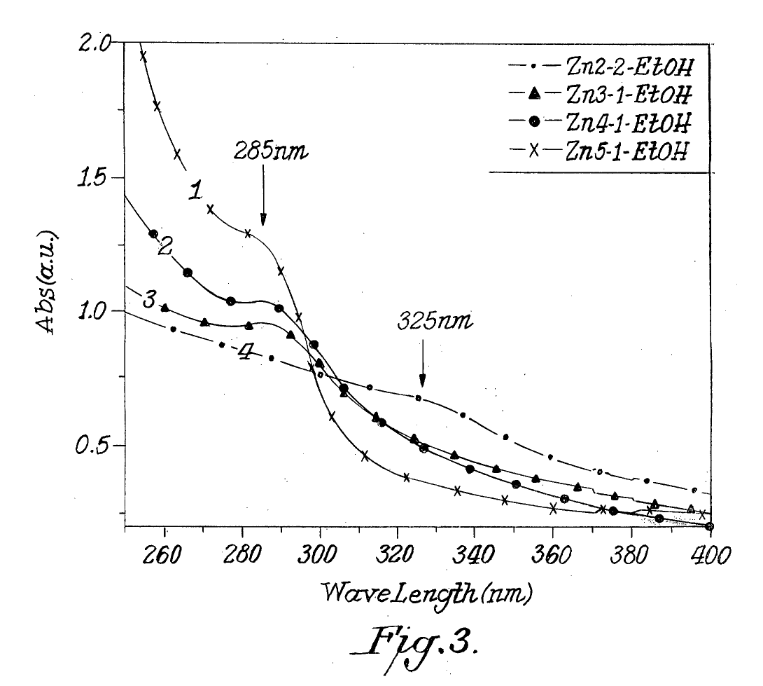

The UV/Vis spectra of ZnS nanoparticles dispersed in ethyl alcohol are shown in FIG. 3. The spectra (curves 1, 2 and 3) for samples obtained in glycerol, ethylene glycol and diethylene glycol at initial stages (150° C., 10 mins) are very similar: absorption peaks are centered at about 285 nm which are strongly blue-shifted indicating a smaller particle size of about 2.5 nm comparing with the curve 4 for sample obtained at 150-160° C. for 2 hours in which only a shoulder appears at about 325 nm corresponding to the onset of UV absorption. According to the empirical relationship between the average size of ZnS nanoparticles and the onset of UV absorption given by Banfield et al., (Zhang H.; Gilbert B.; Huang F.; Banfield J. F. Nature, 2003, 424, 1025) we estimate the particle size to be about 4.5 nm, which is in good agreement with TEM observation.

To examine whether TMAH induced the formation of hexagonal ZnS NCs at such low temperature, we performed similar experiment without TMAH. We still obtained hexagonal ZnS NCs evidenced from XRD data. The only difference is the product has white color mixed with light pink instead of light yellow. Using other polyols such as diethylene glycol and glycerol without TMAH (see FIG. 2), we also obtained hexagonal ZnS NCs. Therefore, we tend to conclude that polyol plays a key role in forming hexagonal ZnS NCs at low temperatures. Polyol probably forms some intermediates with ZnS like the one reported in Ref. 5e which, however, can decomposes into wurtzite ZnS at lower temperatures. The exact mechanism is not known at this moment.

To summarize, we have synthesized close to monodispersed hexagonal ZnS NCs at temperature as low as 150° C. in polyol medium. This method should also apply to the synthesis of other II-VI semiconductor NCs like CdS. Further, the method may be readily used for doping these II-VI semiconductor nanocrystals with transition metals like Cr, V and Mn. This work is helpful for better understanding the crucial factor determining the crystal structure of nanosized semiconductors.

All the references described above are incorporated by reference in its entirety for all useful purposes.

While there is shown and described certain specific structures embodying the invention, it will be manifest to those skilled in the art that various modifications and rearrangements of the parts may be made without departing from the spirit and scope of the underlying inventive concept and that the same is not limited to the particular forms herein shown and described.

We claim:

1. A method to produce a semiconductor nanocrystal which comprises dissolving a metal source in a first solvent that contains at least one functional —OH group to form a mixture and heating the mixture to form a solution 1 and
dissolving a X source in a second solvent which contains at least one functional —OH group, to form a solution 2, wherein the X source contains at least one element of the Group 15 or 16 of the periodic table, and mixing solution 2 and then combining solution 2 with solution 1, and heating and separating out the semiconductor nanocrystal.

2. The method as claimed in claim 1, wherein the semiconductor nanocrystal is CdS, PbS, HgS or ZnS.

3. The method as claimed in claim 1, wherein the metal source is a metal halide or a metal acetate.

4. The method as claimed in claim 3, wherein the metal acetate is ZnAc₂ CdAc₂, PbAc₂ or HgAc₂.

5. The method as claimed in claim 3, wherein the metal halide is a metal chloride.

6. The method as claimed in claim 2, wherein the metal source is ZnAc₂ CdAc₂, PbAc₂ or HgAc₂.

7. The method as claimed in claim 2, wherein the metal source is CdCl₂, PbCl₂, HgCl₂ or ZnCl₂.

8. The method as claimed in claim 5, wherein the metal chloride is CdCl₂, PbCl₂, HgCl₂ or ZnCl₂.

9. The method as claimed in claim 1, wherein the semiconductor nanocrystal is zinc sulfide and the metal source is zinc halide.

10. The method as claimed in claim 1, which further comprises a surfactant dissolved in solution 1.

11. The method as claimed in claim 10, wherein the surfactant contains hydroxide.

12. The method as claimed in claim 11, wherein the solvent is tetramethylammonium hydroxide.

13. A method for doping a semiconductor which comprises doping the semiconductor as produced by claim 1 with transition metal.

14. The method as claimed in claim 13, wherein the transitional metal is selected from the group consisting of Ag, Cu, Co, Cr, V and Mn.
